(19) United States
(12) Patent Application Publication
(10) Pub. No.: US 2024/0371803 A1
(43) Pub. Date: Nov. 7, 2024

(54) METHOD FOR FORMING A REDISTRIBUTION LAYER STRUCTURE, AND CHIP PACKAGE STRUCTURE

(71) Applicant: TAIWAN SEMICONDUCTOR MANUFACTURING COMPANY, LTD., Hsinchu (TW)

(72) Inventors: Jui-Wen SU, Hsinchu (TW); Shi-Hua TZENG, Hsinchu (TW); Tsung-Huan WU, Hsinchu (TW); Po-Chi WU, Hsinchu (TW)

(73) Assignee: TAIWAN SEMICONDUCTOR MANUFACTURING COMPANY, LTD., Hsinchu (TW)

(21) Appl. No.: 18/310,144

(22) Filed: May 1, 2023

(51) Int. Cl. H01L 23/00

(52) U.S. Cl. CPC H01L 24/03; H01L 24/05; H01L 24/13; H01L 2224/02311; H01L 2224/02313; H01L 2224/02333; H01L 2224/0401; H01L 2224/13147

(57) ABSTRACT

A method is provided for forming a redistribution layer (RDL) structure. An RDL feature is formed over a die, and the RDL feature is electrically connected to a contact of the die. A passivation layer is formed over the RDL feature. A patterned etch mask layer is formed over the passivation layer, and has an opening over a portion of the RDL feature. The passivation layer is patterned using the patterned etch mask layer disposed thereon. The patterned etch mask layer is removed after the passivation layer is patterned using the patterned etch mask layer disposed thereon. The passivation layer is etched to form a passivation opening in the passivation layer, and the portion of the RDL feature is exposed through the passivation opening.

### BACKGROUND

The semiconductor integrated circuit (IC) industry has over the past decades experienced tremendous advancements and is still experiencing vigorous development. However, advances in IC design need to be accompanied by improvements in packaging in order to optimize device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating steps of a method for forming a redistribution layer (RDL) structure in accordance with a first embodiment.

FIGS. 2 through 12 are sectional views illustrating the first embodiment.

FIG. 13 shows schematic diagrams that exemplarily depict an RDL structure manufactured by the first embodiment.

FIG. 14 is a sectional view illustrating an exemplary application of the RDL structure formed by the first embodiment.

FIG. 15 is a flow chart illustrating steps of a method for forming an RDL structure in accordance with a second embodiment.

FIGS. 16 and 17 are sectional views that cooperate with FIGS. 2 through 11 to illustrate the second embodiment.

FIG. 18 shows schematic diagrams that exemplarily depict an RDL structure manufactured by the second embodiment.

FIG. 19 is a flow chart illustrating steps of a method for forming an RDL structure in accordance with a third embodiment.

FIGS. 20 through 22 are sectional views that cooperate with FIGS. 2 through 11 to illustrate the third embodiment.

FIG. 23 shows schematic diagrams that exemplarily depict an RDL structure manufactured by the third embodiment.

FIGS. 24 through 29 are sectional views illustrating an exemplary process to form a solder ball over the RDL structure formed by the third embodiment.

FIG. 30 is a sectional view illustrating an exemplary application of the RDL structure formed by the third embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

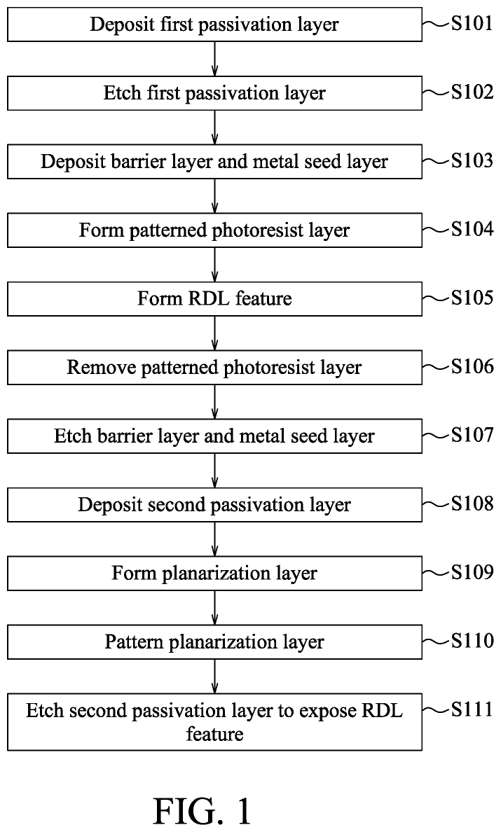

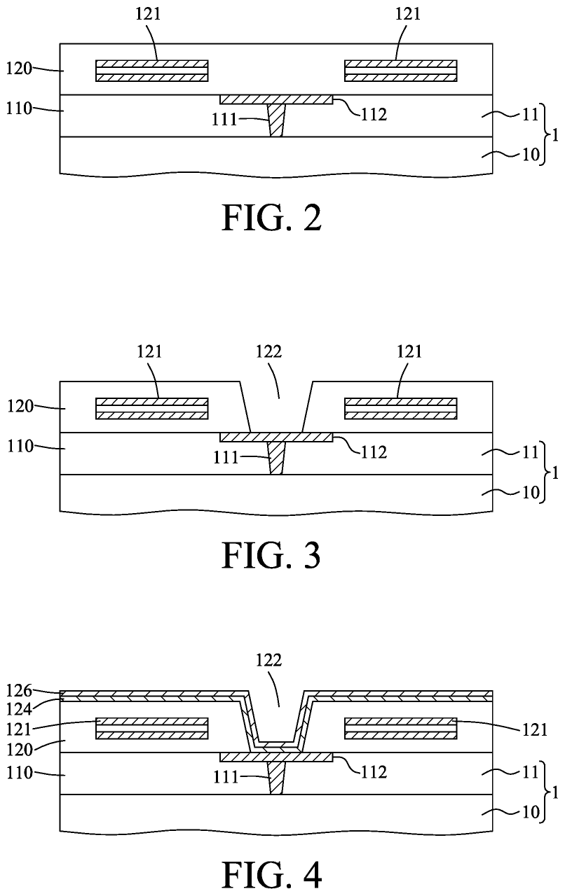

In semiconductor packaging, redistribution layer (RDL) is an extra layer of wiring that is formed over a chip die in order to reroute connections to desired locations. FIG. 1 is a flow chart that cooperates with FIGS. 2 through 12 to illustrate steps of a method for forming an RDL structure in accordance with a first embodiment.

Referring to FIGS. 1 and 2, a chip die 1 is provided, and a first passivation layer 120 is deposited over the chip die 1 (step S101). The chip die 1 is illustrated to include a substrate 10, and a top connection layer 11 formed over the substrate 10. The substrate 10 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The substrate 10 may be made of a suitable semiconductor material, such as silicon or the like. In some embodiments, the substrate 10 is a silicon substrate; and in other embodiments, the substrate 10 is made of a compound semiconductor such as silicon carbide, gallium arsenide, indium arsenide, indium phosphide or other suitable materials. In still other embodiments, the substrate 10 is made of an alloy semiconductor such as GaAsP, AlInAs, AlGaAs, GaInAs, GaInP, GaInAsP or other suitable materials.

In some embodiments, the substrate 10 includes various p-type doped regions and/or n-type doped regions, such as p-type wells, n-type wells, p-type source/drain features and/or n-type source/drain features (source/drain feature(s) may refer to a source or a drain, individually or collectively depending upon the context), formed by a suitable process such as ion implantation, thermal diffusion, a combination thereof, or the like. In some embodiments, the substrate 10 may include other functional elements such as resistors, capacitors, diodes, transistors, and/or the like. The transistors are, for example, field effect transistors (FETs), such as planar FETs and/or 3D FETs (e.g., FinFETs, GAAFETs). The substrate 10 may include lateral isolation features (e.g., shallow trench isolation (STI)) configured to separate various functional elements formed on the substrate 10 and/or various functional elements formed in the substrate 10. In accordance with some embodiments, the substrate 10 may be formed with a plurality of interconnection layers over the layers of the functional elements, and the top connection layer 11 is formed over the interconnection layers.

In the illustrative embodiment, the top connection layer 11 includes a dielectric layer 110 and a connection structure formed in the dielectric layer 110, where the connection structure includes a connection via 111 and a contact 112. The contact 112 may be electrically connected to one or more functional elements that are disposed in the substrate 10 through the connection via 111 and the interconnection layers, and is disposed on top of the chip die 1 for signal transmission between the chip die 1 and external circuits (e.g., circuits of another chip die, circuits on a printed circuit board, etc.). In accordance with some embodiments, the dielectric layer 110 may include, for example, undoped silicate glass (USG), other suitable materials, or any combination thereof, and the connection structure may include, for example, Cu, Ni, Co, Ru, Ir, Al, Pt, Pd, Au, Ag, Os, W, Mo, related alloys, other suitable materials, or any combination thereof. In accordance with some embodiments, the first passivation layer 120 may include, for example, silicon nitride (SiₓN_{y}), silicon carbon nitride (SiₓC_{y}N_{z}), other suitable dielectric materials, or any combination thereof, and may be formed using, for example, chemical vapor deposition (CVD), other suitable techniques, or any combination thereof. In accordance with some embodiments, the first passivation layer 120 may be of either a single layer structure or a multilayer structure. In the illustrative embodiments, some functional components 121 may be formed in the first passivation layer 120. For example, the functional components 121 may be metal-insulator-metal (MIM) components, other types of functional components, or any combination thereof. In accordance with some embodiments, no functional components are formed in the first passivation layer 120.

Referring to FIGS. 1 and 3, the first passivation layer 120 is etched (step S102) to form a via hole 122 in the first passivation layer 121, where the via hole 122 corresponds in position to the contact 112, so that the contact 112 is revealed through the via hole 122. In accordance with some embodiments, the first passivation layer 120 may be etched using, for example, dry etching, other suitable techniques, or any combination thereof.

Referring to FIGS. 1 and 4, a barrier layer 124 is conformally deposited over the first passivation layer 120 and in the via hole 122, and a metal seed layer 126 is conformally deposited over the barrier layer 124 and in the via hole 122 (step S103). In accordance with some embodiments, the barrier layer 124 may include, for example, Ta, TaN, Ti, TiN, other suitable materials, or any combination thereof, and may be formed using, for example, physical vapor deposition (PVD), atomic layer deposition (ALD), other suitable techniques, or any combination thereof. In accordance with some embodiments, the metal seed layer 126 may include Cu, Au, Cu—Al alloys, other suitable materials, or any combination thereof, and may be formed using, for example, PVD, ALD, other suitable techniques, or any combination thereof.

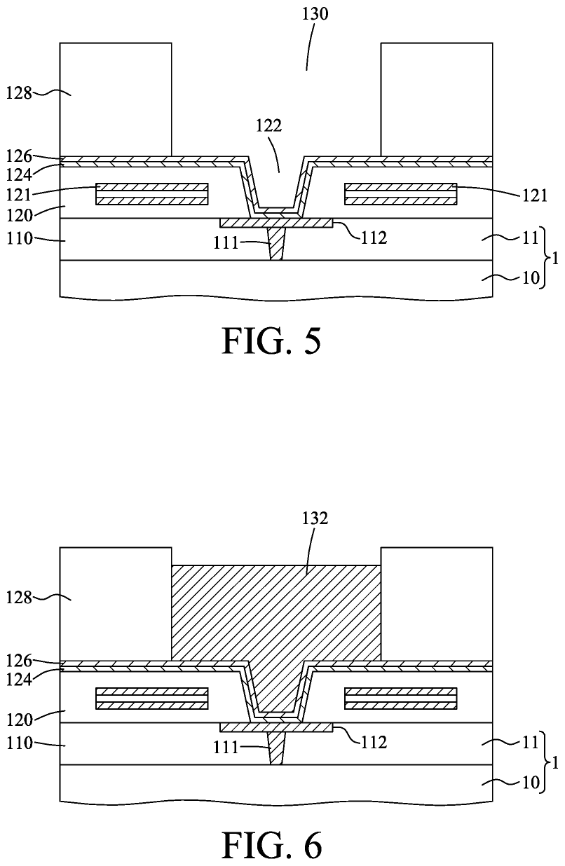

Referring to FIGS. 1 and 5, a patterned photoresist layer 128 is formed (step S104) over the metal seed layer 126, and the patterned photoresist layer 128 has an opening 130 in spatial communication with the via hole 122. In accordance with some embodiments, the opening 130 may be, for example, a trench that extends above the contact 112 and the via hole 122. In accordance with some embodiments, the patterned photoresist layer 128 may be formed by spin coating, exposure, and developing, but this disclosure is not limited to such. In accordance with some embodiments, the opening 130 is wider than the via hole 122 to compensate for overlay errors, but this disclosure is not limited in this respect.

Referring to FIGS. 1 and 6, a conductive material is formed to fill the via hole 122 and the opening 130 (see FIG. 5), so as to form an RDL feature 132 (step S105). In accordance with some embodiments, the RDL feature 132 may include, for example, Cu, Au, Cu—Al alloys, other suitable metal materials, other suitable materials, or any combination thereof, and may be formed using, for example, electroplating, PVD, CVD, other suitable techniques, or any combination thereof. Since the metal seed layer 126 is exposed in the via hole 122 and the opening 130, the RDL feature 132 grows on the metal seed layer 126, and is thus electrically connected to the contact 112. The barrier layer 124 may prevent diffusion of metal elements in the RDL feature 132 into the first passivation layer 120.

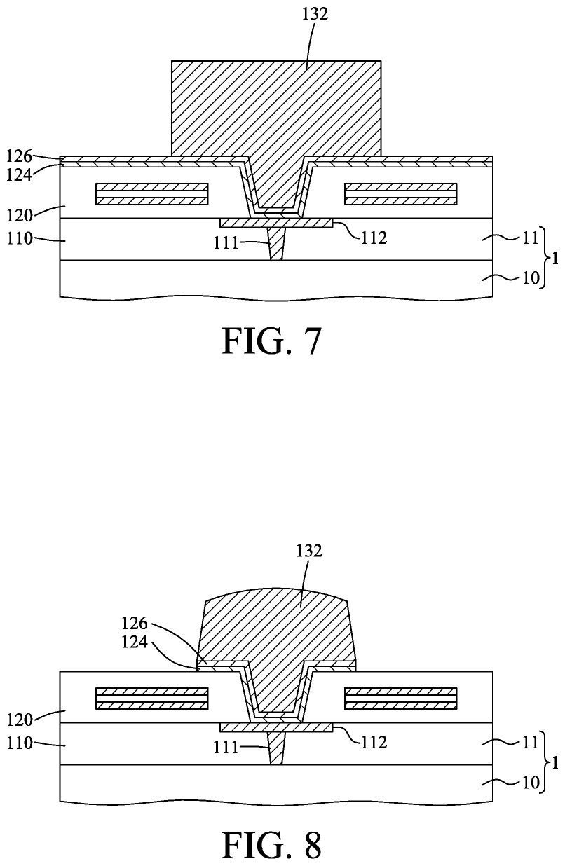

Referring to FIGS. 1 and 7, the patterned photoresist layer 128 is removed (step S106), and a portion of the metal seed layer 126 that is outside of a coverage of the RDL feature 132 is exposed.

Referring to FIGS. 1 and 8, the metal seed layer 126 and the barrier layer 124 are etched (step S107) to remove the portion of the metal seed layer 126 and a portion of the barrier layer 124 that are outside of the coverage of the RDL feature 132, and a portion of the metal seed layer 126 and a portion of the barrier layer 124 that are covered by and correspond in position to the RDL feature 132 remain. In accordance with some embodiments, the metal seed layer 126 may be etched first, followed by etching the barrier layer 124. In accordance with some embodiments, the metal seed layer 126 and the barrier layer 124 may be etched using, for example, wet etching, dry etching, other suitable techniques, or any combination thereof.

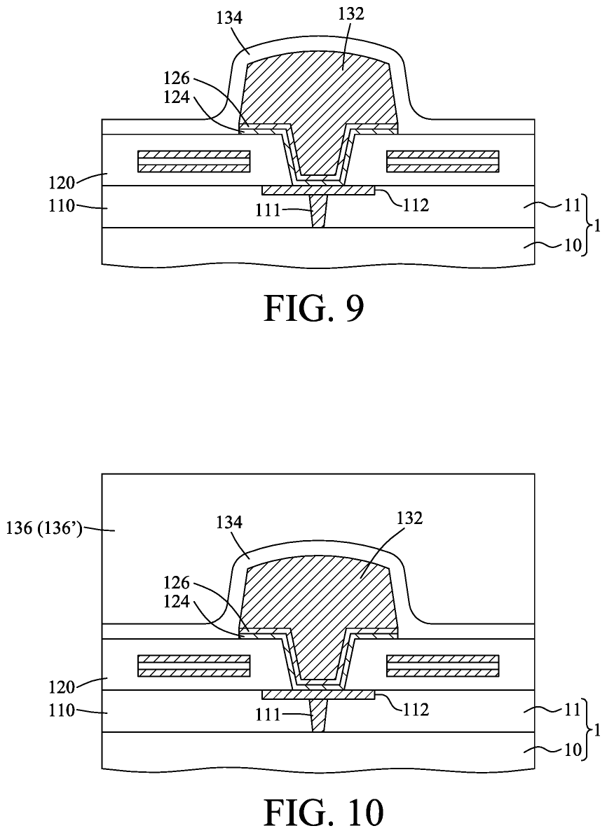

Referring to FIGS. 1 and 9, a second passivation layer 134 is conformally deposited over the first passivation layer 120, lateral portions of the metal seed layer 126 and the barrier layer 124, and the RDL feature 132 (step S108), so the RDL feature 132 is covered by the second passivation layer 134. In accordance with some embodiments, the second passivation layer 134 may include, for example, silicon nitride, other suitable materials, or any combination thereof, and may be formed using, for example, CVD, ALD, other suitable material, or any combination thereof. In accordance with some embodiments, the second passivation layer 134 is formed to have a thickness in a range from about 10000 angstroms to about 13000 angstroms.

Referring to FIGS. 1 and 10, a planarization layer 136 is formed over the second passivation layer 134 (step S109). In accordance with some embodiments, the planarization layer 136 may include, for example, a polymer material (e.g., polyimide (PI)), other suitable materials, or any combination thereof, and may be formed using, for example, spin coating, other suitable techniques, or any combination thereof.

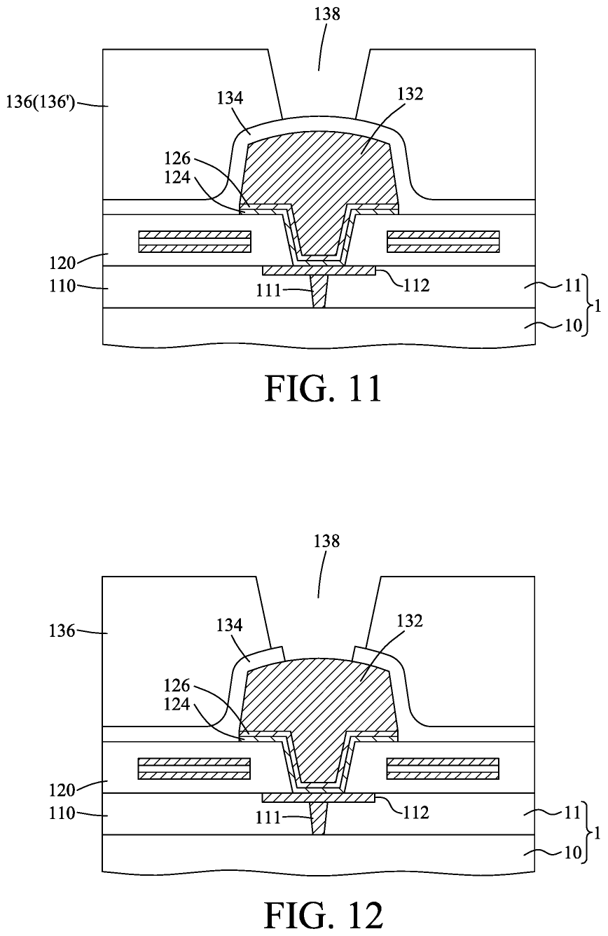

Referring to FIGS. 1 and 11, the planarization layer 136 is patterned to form an opening 138 above the RDL feature 132 (step S110), and a portion of the second passivation layer 134 is exposed through the opening 138. In the illustrative embodiment, the opening 138 corresponds in position to the contact 112 in a thickness direction (i.e., a top-down direction in FIG. 11). In some embodiments, the opening 138 may be formed at a position that does not correspond in position to the contact 112, and this disclosure is not limited in this respect. In accordance with some embodiments, the opening 138 may be formed using exposure and developing processes when the planarization layer 136 is made of a photosensitive material, such as polyimide.

Referring to FIGS. 1 and 12, the second passivation layer 134 is etched (step S111) with the planarization layer 136 serving as an etch mask to form an opening in the second passivation layer 134 (referred to as passivation opening hereinafter), and as a result, the RDL feature 132 is exposed through the passivation opening. In accordance with some embodiments, the second passivation layer 134 may be etched using, for example, dry etching, other suitable techniques, or any combination thereof. In accordance with some embodiments where the second passivation layer 134 is a silicon nitride layer, the dry etching may be performed using, for example, CHF₃ and CF₄, other suitable etchants, or any combination thereof. In accordance with some embodiments where the second passivation layer 134 is a silicon nitride layer, instead of using CHF₃ and CF₄, the dry etching may be performed using a carbon-free etchant, such as NF₃, which does not include element carbon, so that no fluorocarbon polymer particles will be formed during the etching process, and some adverse effects that may result from the fluorocarbon polymer particles can be avoided. For example, the fluorocarbon polymer particles may fall onto the surface of the exposed part of the second passivation layer 134 because of their heavy weight, and may thus restrain the etching of the second passivation layer 134. In addition, using NF₃ as the etchant for the dry etching may lead to a higher etching rate than using CHF₃ and CF₄, thereby achieving a better economic efficiency. Other suitable carbon-free etchants may be used in the dry etching in other embodiments to achieve similar effects, and this disclosure is not limited in this respect. In the illustrative embodiment, the planarization layer 136 is further etched such that a bottom portion of the opening 138 of the planarization layer 136 is greater in width than a top portion of the passivation opening, so a part of a top surface of the second passivation layer 134 is exposed, and such that the resultant structure may be stronger against stress that may occur in subsequent packaging processes (e.g., a bumping process). As a result, a portion of the RDL feature 132 is exposed through the passivation opening and the opening 138 of the planarization layer 136, and serves as a redistribution contact pad for use in subsequent packaging processes.

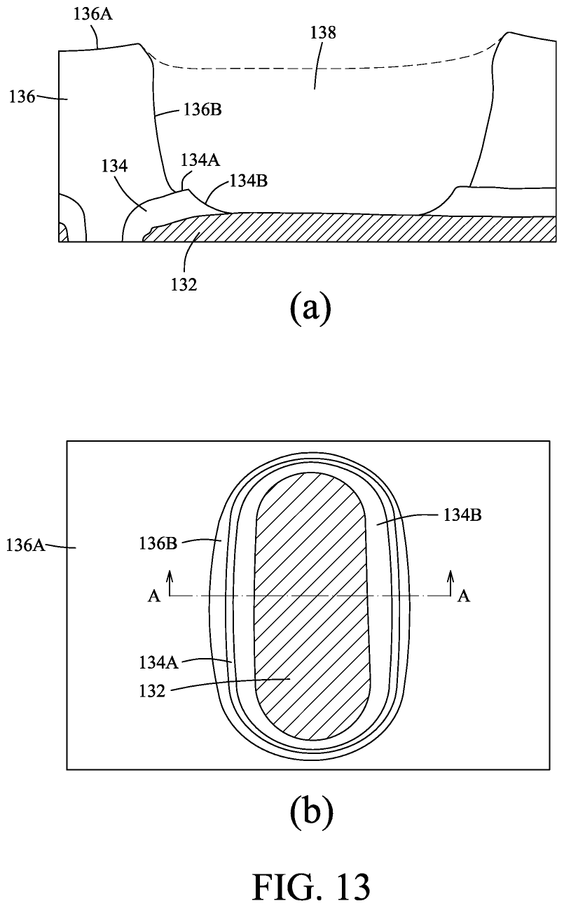

FIG. 13 provides schematic diagrams that exemplarily depict an RDL structure manufactured by the process as shown in FIG. 1, where part (b) of FIG. 13 shows a top view of the RDL structure, and part (a) of FIG. 13 shows a sectional view of the RDL structure taken along line A-A in part (b). A top surface 136A of the planarization layer 136 is formed with the opening 138 that has a sidewall 136B. It can be seen that: the sidewall 136B of the opening 138 is steeper than a sidewall 134B of the passivation opening; the RDL feature 132 is exposed through the passivation opening and the opening 138 of the planarization layer 136; and a part of the top surface 134A of the second passivation layer 134 that is adjacent to and surrounds the passivation opening is exposed through the opening 138 of the planarization layer 136.

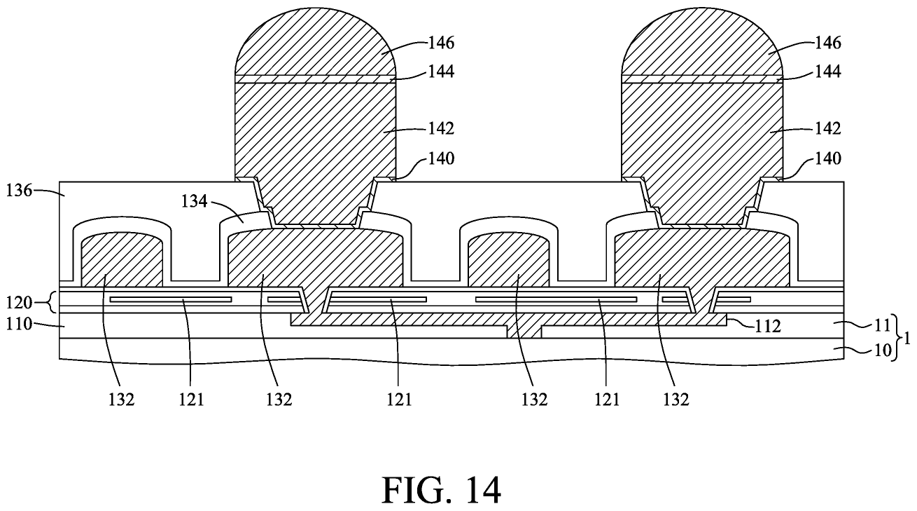

FIG. 14 illustrates a sectional view of an exemplary application that includes the RDL structure of the first embodiment. A metal pillar 142 is formed to fill the opening of the planarization layer 136 and protrudes from the planarization layer 136, and a solder ball 146 is formed over the metal pillar 142. In accordance with some embodiments, the metal pillar 142 may include, for example, Au, Cu, other suitable materials, or any combination thereof, and the solder ball 146 may include, for example, Sn, Ag, other suitable materials, or any combination thereof. An under bump metallurgy (UBM) 140 is disposed between the RDL feature 132 and the metal pillar 142. In particular, the UBM 140 is conformally formed in the opening of the planarization layer 136 and over a portion of the top surface of the planarization layer 136, and is disposed between and in contact with the RDL feature 132 and the metal pillar 142. In accordance with some embodiments, the UBM 140 may include, for example, Ti, Cu, Ni, Au, Cr, Al, W, other suitable materials, or any combination thereof. In some embodiments, the UBM 140 may be omitted. A barrier layer 144 is disposed between and in contact with the metal pillar 142 and the solder ball 146. The barrier layer 144 may include, for example, Ni, other suitable materials, or any combination thereof, and is formed to, for example, prevent metal elements in the metal pillar 142 from diffusing into the solder ball 146. In some embodiments, the barrier layer 144 may be omitted. In FIG. 14, the first passivation layer 120 is of a multilayer structure, where a lower layer may be, for example, a silicon carbon nitride layer, and an upper layer may be, for example, a silicon nitride layer, but this disclosure is not limited in this respect.

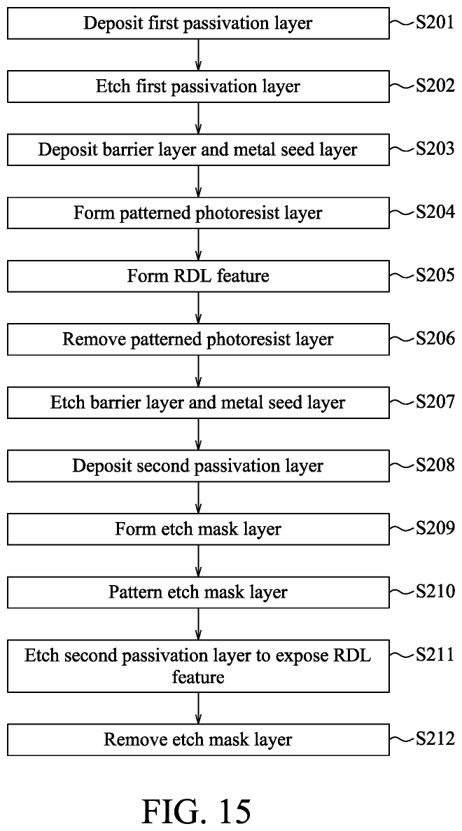

FIG. 15 is a flow chart that illustrates steps of a method for forming an RDL structure in accordance with a second embodiment. In the second embodiment, the second passivation layer 134 is not covered by the planarization layer 136 as in the first embodiment (see FIG. 12), and is a bare passivation layer that is exposed to the air. Without the planarization layer 136, concerns with respect to deviation in processing the planarization layer 136 is eliminated, so openings of the second passivation layer 134 to make redistribution contact pads can be made smaller, pitches among the redistribution contact pads can be reduced, and an amount of solder joints for the chip die 1 can be increased, thereby improving performance and power consumption of the chip die 1. In the second embodiment, steps S201 through S208 may be the same as steps S101 through S108 of the first embodiment (see FIG. 1), so details thereof are not repeated herein for the sake of brevity.

Referring to FIGS. 15 and 10, after step S208 (see FIG. 9, where the second passivation layer 134 is deposited), an etch mask layer 136′ is formed over the second passivation layer 134 (step S209). In accordance with some embodiments, the etch mask layer 136′ may be a photosensitive layer that is made of, for example, polyimide, an ordinary photoresist material that is commonly used in a photolithography process, other suitable materials, or any combination thereof. In accordance with some embodiments, the etch mask layer 136′ may be formed using, for example, spin coating, other suitable techniques, or any combination thereof.

Referring to FIGS. 15 and 11, the etch mask layer 136′ is patterned to form an opening 138 above a portion of the RDL feature 132 (step S210), and a portion of the second passivation layer 134 (referred to as exposed portion of the second passivation layer 134 hereinafter) that corresponds in position to the portion of the RDL feature 132 is exposed through the opening 138 of the patterned etch mask layer 136′. In the illustrative embodiment, the opening 138 corresponds in position to the contact 112 in the thickness direction. In some embodiments, the opening 138 may be formed at a position that does not correspond in position to the contact 112, and this disclosure is not limited in this respect. In accordance with some embodiments, the opening 138 may be formed using exposure and developing processes when the etch mask layer 136′ is made of a photosensitive material, such as polyimide or a photoresist material.

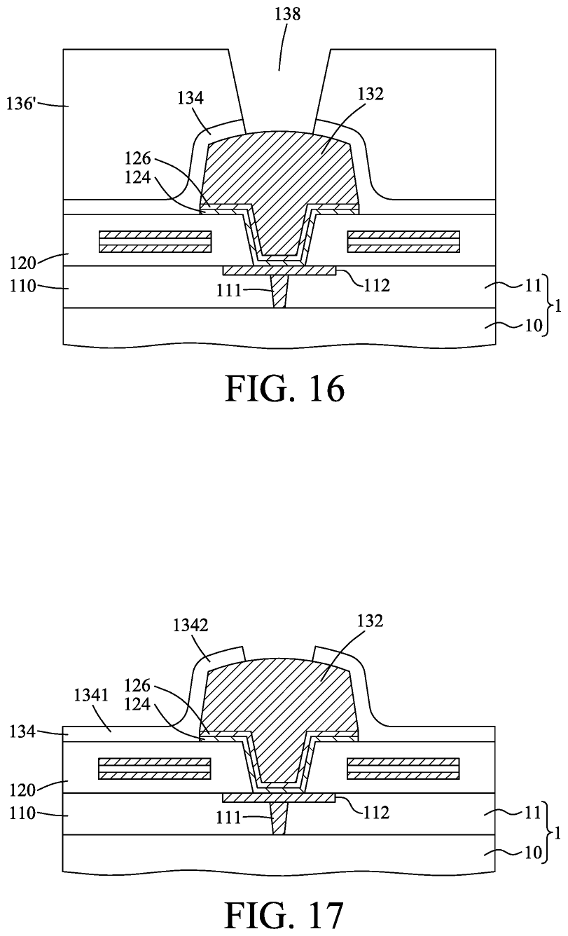

Referring to FIGS. 15 and 16, the second passivation layer 134 is patterned by etching the second passivation layer 134 (step S211) while the second passivation layer 134 is covered by the patterned etch mask layer 136′ to form a passivation opening in the second passivation layer 134, so as to expose the RDL feature 132 through the passivation opening. In other words, the exposed portion of the second passivation layer 134 is etched and removed with the patterned etch mask layer 136′ being disposed on the second passivation layer 134. In accordance with some embodiments, the second passivation layer 134 may be etched using, for example, dry etching, other suitable techniques, or any combination thereof. As a result, a portion of the RDL feature 132 (referred to as exposed portion of the RDL feature hereinafter) is exposed through the passivation opening and the opening 138 of the patterned etch mask layer 136′, and serves as a redistribution contact pad for use in subsequent packaging processes. In the second embodiment, the patterned etch mask layer 136′ does not need to be further etched to form a structure like the planarization layer 136 in FIG. 12 because the patterned etch mask layer 136′ is to be removed in a later process to make the second passivation layer 134 fully exposed to the air. Therefore, the top surface of the second passivation layer 134 remains fully covered by the patterned etch mask layer 136′ after step S211, but this disclosure is not limited to such.

Referring to FIGS. 15 and 17, the patterned etch mask layer 136′ is removed (step S212) using, for example, an ashing process with N₂/O₂ plasmas at a temperature in a range from about 150° C. to 350° C. when the patterned etch mask layer 136′ is a photosensitive layer. In comparison to using polyimide to form the patterned etch mask layer 136′, using an ordinary photoresist material to form the patterned etch mask layer 136′ may make removal of the patterned etch mask layer 136′ easier and faster because the ordinary photoresist material usually has a higher etching rate than polyimide, thereby achieving higher economic efficiency. After removal of the patterned etch mask layer 136′, the second passivation layer 134 becomes a bare passivation layer that is exposed to the air. The second passivation layer 134 includes a plain portion 1341 that is formed over the first passivation layer 120, and a covering portion 1342 that covers and is in contact with the RDL feature 132. To be specific, the covering portion 1342 of the second passivation layer 134 is formed over a sidewall and a part of a top surface of the RDL feature 132, and forms the passivation opening to expose the RDL feature 132.

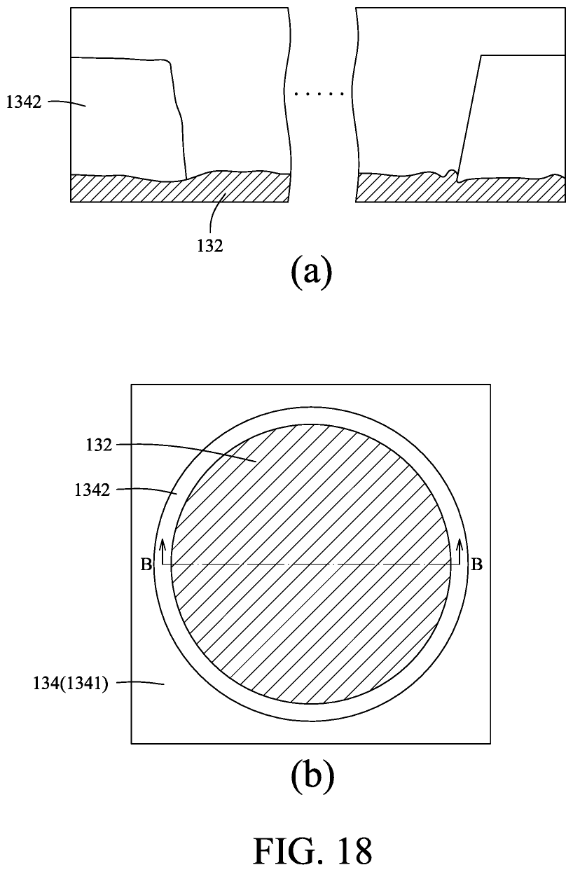

FIG. 18 provides schematic diagrams that exemplarily depict an RDL structure manufactured by the process as shown in FIG. 15, where part (b) of FIG. 18 shows a top view of the RDL structure, and part (a) of FIG. 18 shows a sectional view of the RDL structure taken along line B-B in part (b). In accordance with some embodiments, the second passivation layer 134 may have a thickness in a range from about 10000 angstroms to about 13000 angstroms (i.e., a distance between a top surface of the RDL feature 132 and a top surface of the covering portion 1342 of the second passivation layer 134 in the thickness direction ranges from about 10000 angstroms to about 13000 angstroms).

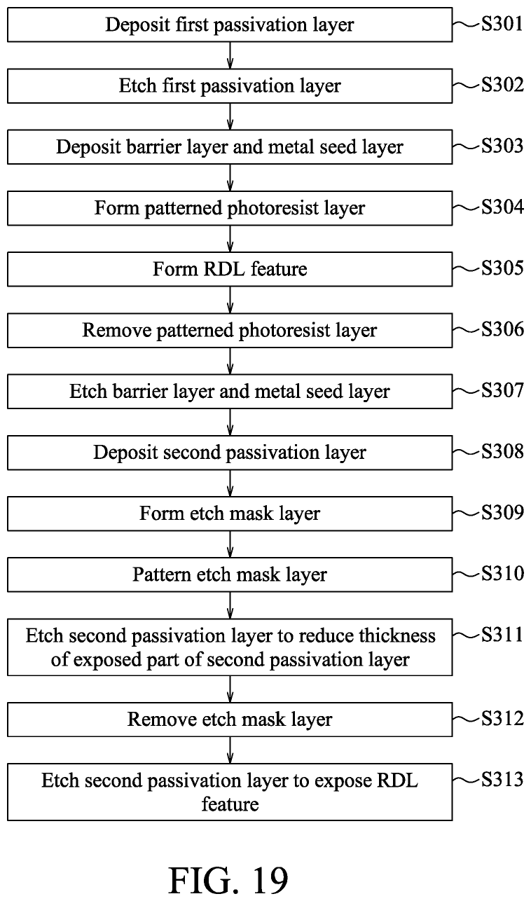

FIG. 19 is a flow chart that illustrates steps of a method for forming an RDL structure in accordance with a third embodiment. Similar to the second embodiment, the second passivation layer 134 of the third embodiment is a bare passivation layer that is exposed to the air. In the third embodiment, steps S301 through S310 are the same as steps S201 through S210 of the second embodiment (see FIG. 15), so details thereof are not repeated herein for the sake of brevity.

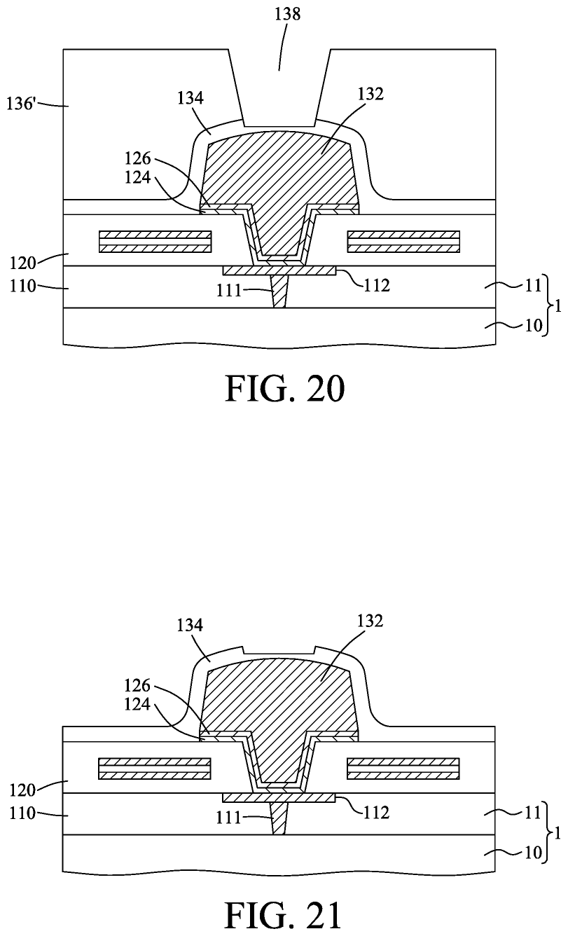

Referring to FIGS. 19 and 20, after the etch mask layer 136′ is patterned to form an opening 138 above the RDL feature 132 in step S310 (see FIG. 11), the second passivation layer 134 is patterned by etching the second passivation layer 134 while the second passivation layer 134 is covered by the patterned etch mask layer 136′ in such a way that a thickness of an exposed portion of the second passivation layer 134 (i.e., a portion of the second passivation layer 134 that is exposed through the opening 138 of the patterned etch mask layer 136′) is reduced but still greater than zero (step S311, the first etching of the second passivation layer 134 in the third embodiment). In other words, the exposed portion of the second passivation layer 134 is etched using the patterned etch mask layer 136′ so as to cover the RDL feature 132 with a reduced thickness. As a result, the exposed portion of the second passivation layer 134 is thinner than other portions of the second passivation layer 134 that are covered by the patterned etch mask layer 136′. In accordance with some embodiments, the second passivation layer 134 may be etched using, for example, dry etching, other suitable techniques, or any combination thereof. In accordance with some embodiments where the second passivation layer 134 is a silicon nitride layer, the dry etching may be performed using CHF₃ and CF₄. In accordance with some embodiments where the second passivation layer 134 is a silicon nitride layer, instead of using CHF₃ and CF₄, the dry etching may be performed using a carbon-free etchant, such as NF₃, which does not include element carbon, so that no fluorocarbon polymer particles will be formed during the etching process, and some adverse effects that may result from the fluorocarbon polymer particles can be avoided. For example, the fluorocarbon polymer particles may fall onto the surface of the exposed part of the second passivation layer 134 because of their heavy weight, and may thus restrain the etching of the second passivation layer 134. In addition, using NF₃ as the etchant of the dry etching may lead to a higher etching rate than using CHF₃ and CF₄, thereby achieving a better economic efficiency. Other suitable carbon-free etchants may be used in the dry etching in other embodiments to achieve similar effects, and this disclosure is not limited in this respect. In accordance with some embodiments, the dry etching may be performed using other suitable etchants, or any combination of the aforesaid etchants, and this disclosure is not limited in this respect.

Referring to FIGS. 19 and 21, the patterned etch mask layer 136′ is removed (step S312) using, for example, an ashing process with N₂/O₂ plasmas at a temperature in a range from about 150° C. to 350° C. when the patterned etch mask layer 136′ is a photosensitive layer. In the third embodiment, since the RDL feature 132 is still fully covered by the second passivation layer 134 in step S312, the top surface of the RDL feature 132 will not be exposed to the O₂ plasma in the ashing process and thus is protected from oxidation. Therefore, degradation in conductivity of the RDL structure can be prevented especially when the RDL feature 132 is made of a material that is easy to oxidize, such as copper.

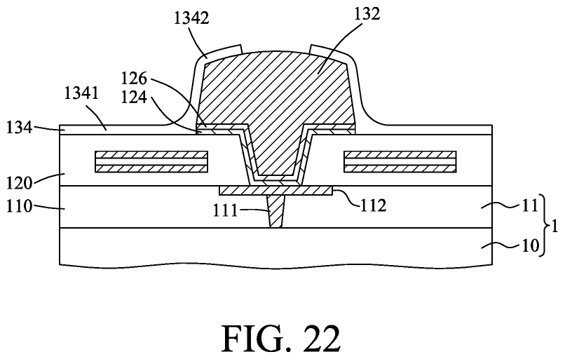

Referring to FIGS. 19 and 22, the second passivation layer 134 is etched (step S313, the second etching of the second passivation layer 134 in the third embodiment) such that a portion of the second passivation layer 134 that has the reduced thickness (i.e., the exposed portion of the second passivation layer 134 in step S311, which is thinner than other portions of the second passivation layer 134 due to the first etching) is removed while the other portions of the second passivation layer 134 remain (i.e., having a thickness greater than zero), so as to form a passivation opening in the second passivation layer 134, through which the RDL feature 132 is exposed. In accordance with some embodiments, the second passivation layer 134 may be etched using, for example, dry etching, other suitable techniques, or any combination thereof. In accordance with some embodiments where the second passivation layer 134 is a silicon nitride layer, the dry etching may be performed using, for example, CHF₃ and CF₄. In accordance with some embodiments where the second passivation layer 134 is a silicon nitride layer, instead of using CHF₃ and CF₄, the dry etching may be performed using a carbon-free etchant, such as NF₃, which does not include element carbon, so that no fluorocarbon polymer particles will be formed during the etching process, and some adverse effects that may result from the fluorocarbon polymer particles can be avoided. For example, the fluorocarbon polymer particles may fall onto the surface of the second passivation layer 134 because of their heavy weight, and may thus cause a rugged top surface of the second passivation layer 134. It is noted that other suitable carbon-free etchants may be used in the dry etching in other embodiments to achieve similar effects, and this disclosure is not limited in this respect. In addition, using NF₃ as the etchant of the dry etching may lead to a higher etching rate than using CHF₃ and CF₄, thereby achieving a better economic efficiency. As a result, a part of the RDL feature 132 is exposed in the passivation opening, and serves as a redistribution contact pad for use in subsequent packaging processes. In step S313, since the second passivation layer 134 is completely exposed to the etchant that is used to etch the second passivation layer 134, an overall thickness of the second passivation layer 134 is reduced. In accordance with some embodiments, after the second etching, the thickness of the second passivation layer 134 is reduced to from about 5000 angstroms to about 11000 angstroms. In accordance with some embodiments, after the second etching, the thickness of the second passivation layer 134 is reduced to from about 5000 angstroms to about 8000 angstroms. When the remaining thickness of the second passivation layer 134 is too small (e.g., smaller than 5000 angstroms), resistance to the stress that may occur in subsequent packaging processes (e.g., the bumping process) may be insufficient, and thus an adverse effect may be brought upon the result of a subsequent wafer acceptance test (WAT). The remaining thickness of the second passivation layer 134 being too large (e.g., greater than 11000 angstroms) may result from excessive etching of the second passivation layer 134 in the first etching of the second passivation layer 134, and excessive etching of the second passivation layer 134 in the first etching of the second passivation layer 134 may cause some portions of the second passivation layer 134 to be undesirably removed because of process deviations, which may undesirably expose part of the RDL feature 132 prior to the second etching of the second passivation layer 134. Similar to the second embodiment, the second passivation layer 134 of the third embodiment is a bare passivation layer that is exposed to the air. The second passivation layer 134 includes a plain portion 1341 that is formed over the first passivation layer 120, and a covering portion 1342 that covers and is in contact with the RDL feature 132. The covering portion 1342 of the second passivation layer 134 is formed over a sidewall and a part of a top surface of the RDL feature 132, and forms the passivation opening to expose the RDL feature 132. The RDL structure formed by the third embodiment differs from the RDL structure formed by the second embodiment in that the second passivation layer 134 of the third embodiment is thinner than the second passivation layer 134 of the second embodiment because of the second etching of the second passivation layer 134.

It is noted that, in step S311, the second passivation layer 134 may be etched such that the exposed portion of the second passivation layer 134 has a thickness (i.e., the reduced thickness) in a range from about 2500 angstroms to about 4500 angstroms in accordance with some embodiments. When the reduced thickness of the exposed portion of the second passivation layer 134 in step S311 is too small (e.g., smaller than 2500 angstroms), process deviation may cause some other portions of the second passivation layer 134 to be fully removed undesirably. When the reduced thickness of the exposed portion of the second passivation layer 134 in step S311 is too large (e.g., greater than 4500 angstroms), the etching window for the second etching may be too small to form the passivation opening, or the second etching may cause the second passivation layer 134 to be too thin to effectively resist the stress that may occur in subsequent packaging processes (e.g., the bumping process).

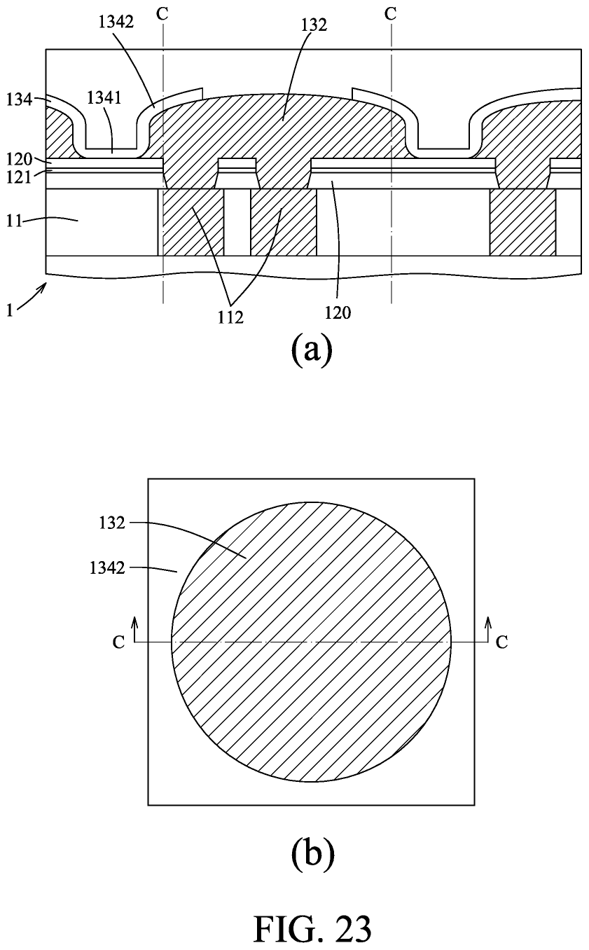

FIG. 23 provides schematic diagrams that exemplarily depict an RDL structure manufactured by the process as shown in FIG. 19, where part (a) of FIG. 23 shows a sectional view of the RDL structure, and a segment between chain lines C illustrates a sectional view taken along line C-C in part (b) of FIG. 23, which is a top view of the RDL structure. In the illustrative embodiment, the central RDL feature 132 is electrically connected to multiple contacts 112 of the chip die 1 through two vias, respectively. In accordance with some embodiments, the second passivation layer 134 may have a thickness in a range from about 5000 angstroms to about 11000 angstroms (i.e., a distance between a top surface of the RDL feature 132 and a top surface of the covering portion 1342 of the second passivation layer 134 in the thickness direction ranges from about 5000 angstroms to about 11000 angstroms).

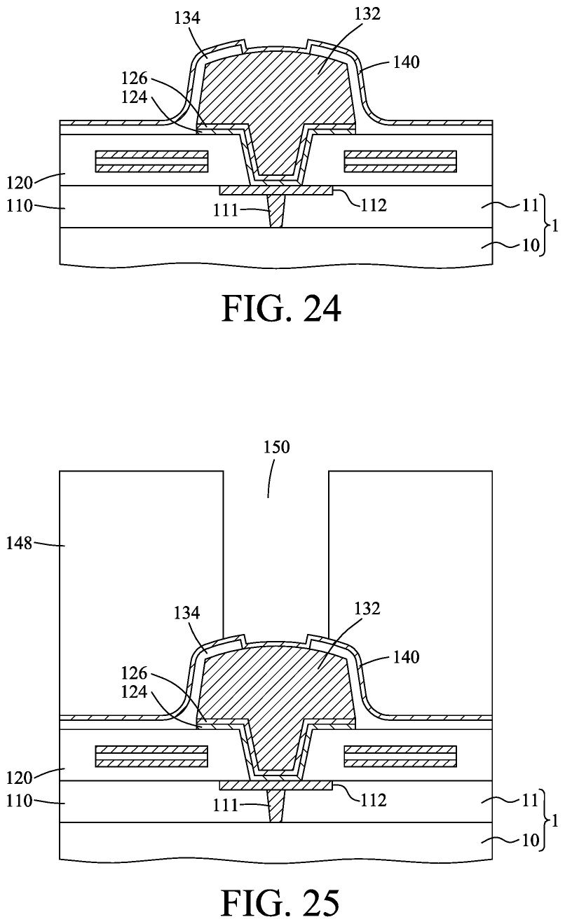

FIGS. 24 through 29 illustrate an exemplary process to form a solder ball over the redistribution contact pad that is formed by the third embodiment.

In FIG. 24, a conductive layer 140 is conformally deposited over the second passivation layer 134 and the exposed portion of the RDL feature 132 that is exposed through the passivation opening. The conductive layer 140 may include, for example, Ti, Cu, Ni, Au, Cr, Al, W, other suitable materials, or any combination thereof, and may be formed using, for example PVD, CVD, ALD, other suitable techniques, or any combination thereof. The conductive layer 140 may be of either a single layer structure or a multilayer structure.

In FIG. 25, a patterned photoresist layer 148 is formed over the conductive layer 140. The patterned photoresist layer 148 has an opening 150 that corresponds in position to the redistribution contact pad and that exposes a portion of the conductive layer 140.

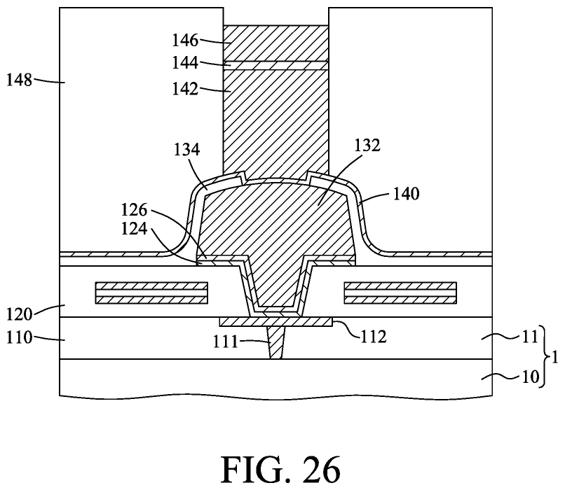

In FIG. 26, a metal pillar 142, a barrier layer 144 and a solder feature 146 are formed in the opening 150 (see FIG. 25) in sequence and are electrically connected to the RDL feature 132 through the conductive layer 140. In accordance with some embodiments, the metal pillar 142 may include, for example, Au, Cu, other suitable materials, or any combination thereof, the barrier layer 144 may include, for example, Ni, other suitable materials, or any combination thereof, and the solder feature 146 may include, for example, Sn, Ag, other suitable materials, or any combination thereof.

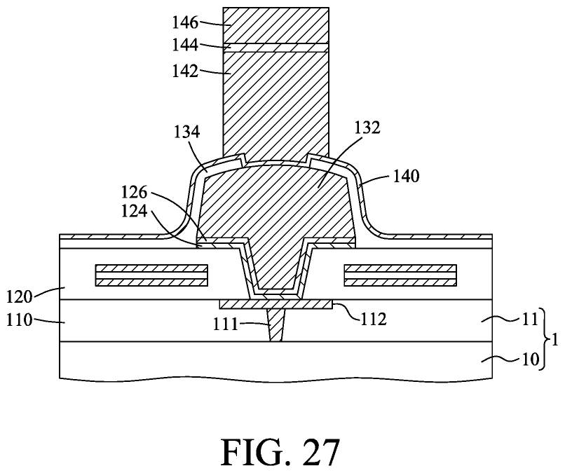

In FIG. 27, the patterned photoresist layer 148 (see FIG. 26) is removed, and a portion of the conductive layer 140 that is outside of a coverage of the metal pillar 142 is exposed.

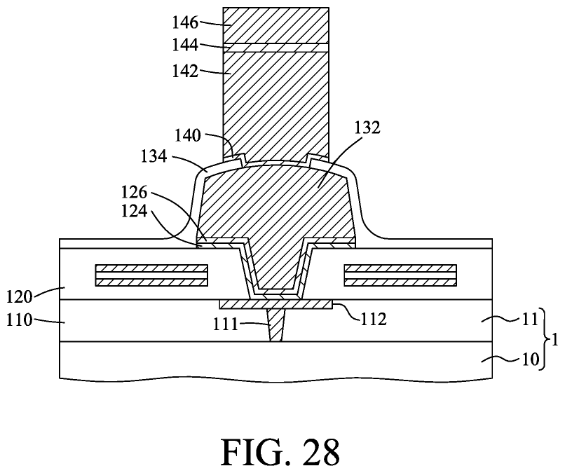

In FIG. 28, the portion of the conductive layer 140 that is outside of the coverage of the metal pillar 142 is removed to form an UBM feature (also denoted by numeral 140).

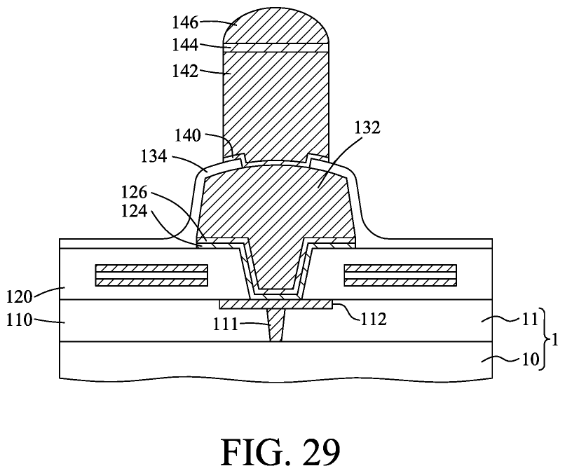

In FIG. 29, a reflow process is performed to transform the solder feature 146 into a solder ball 146.

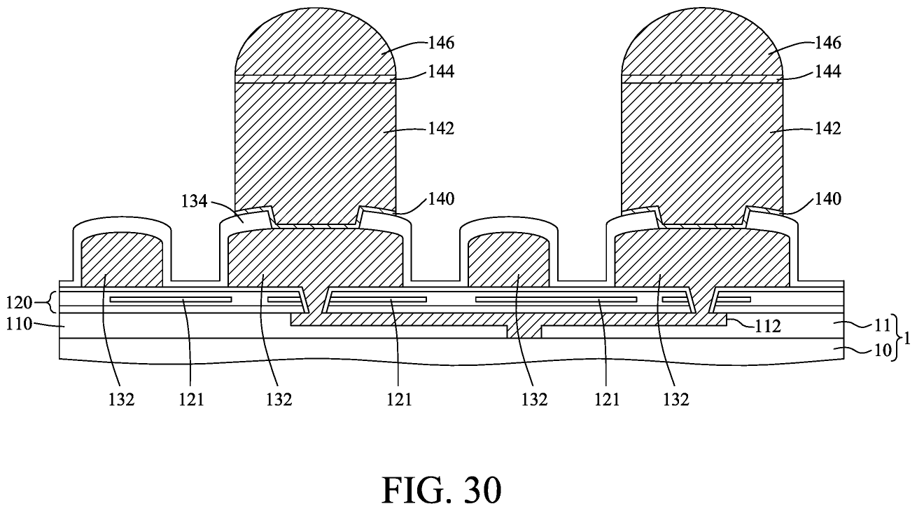

FIG. 30 illustrates a sectional view of an exemplary application that includes the RDL structure of the third embodiment. For the second RDL feature 132 from the left and for the rightmost RDL feature, a metal pillar 142 is formed to fill the passivation opening and protrudes from the second passivation layer 134, and a solder ball 146 is formed over the metal pillar 142. The UBM 140 is disposed between and in contact with the RDL feature 132 and the metal pillar 142. The barrier layer 144 is disposed between and in contact with the metal pillar 142 and the solder ball 146. In some embodiments, the UBM 140 may be omitted, in which case the metal pillar 142 is in direct contact with the RDL feature 132. In some embodiments, the barrier layer 144 may be omitted, in which case the solder ball 146 is in direct contact with the metal pillar 142.

In accordance with some embodiments, a method for forming a redistribution layer (RDL) structure is provided. In one step, an RDL feature is formed over a die that is provided with a contact. The RDL feature is electrically connected to the contact. In one step, a passivation layer is formed over the RDL feature. In one step, a patterned etch mask layer is formed over the passivation layer. The patterned etch mask layer has an opening over a portion of the RDL feature. In one step, the passivation layer is patterned using the patterned etch mask layer disposed on the passivation layer. In one step, the patterned etch mask layer is removed after the passivation layer is patterned using the patterned etch mask layer disposed on the passivation layer. In one step, the passivation layer is etched to form a passivation opening in the passivation layer. The portion of the RDL feature is exposed through the passivation opening.

In accordance with some embodiments, the patterned etch mask layer is a photoresist layer, and the step of etching the passivation layer to form the passivation opening is performed after the step of removing the patterned etch mask layer.

In accordance with some embodiments, in the step of forming the patterned etch mask layer, the opening of the patterned etch mask layer is formed to expose a portion of the passivation layer. In the step of patterning the passivation layer, the passivation layer is etched using the patterned etch mask layer disposed on the passivation layer to make the portion of the passivation layer cover the RDL feature with a reduced thickness.

In accordance with some embodiments, the reduced thickness of the portion of the passivation layer ranges from 2500 angstroms to 4500 angstroms.

In accordance with some embodiments, after the passivation opening is formed, the passivation layer has a thickness ranging from 5000 angstroms to 11000 angstroms.

In accordance with some embodiments, after the patterned etch mask layer is removed, the portion of the passivation layer is thinner than other portions of the passivation layer. In the step of etching the passivation layer to form the passivation opening, the passivation layer is completely exposed to an etchant that is used to etch the passivation layer.

In accordance with some embodiments, the etchant used in the step of etching the passivation layer to form the passivation opening is a carbon-free etchant.

In accordance with some embodiments, the etchant used in the step of etching the passivation layer to form the passivation opening is NF₃.

In accordance with some embodiments, the etchant used for etching the passivation layer using the patterned etch mask layer disposed on the passivation layer is NF₃.

In accordance with some embodiments, the RDL feature is made of Cu.

In accordance with some embodiments, the patterned etch mask layer is a photoresist layer, and the step of etching the passivation layer to form the passivation opening is performed between the step of patterning the passivation layer and the step of removing the patterned etch mask layer.

In accordance with some embodiments, the etchant used in the step of etching the passivation layer to form the passivation opening is NF₃.

In accordance with some embodiments, a method for forming a redistribution layer (RDL) structure is provided. In one step, an RDL feature is formed over a die that is provided with a contact. The RDL feature is electrically connected to the contact. In one step, a passivation layer is formed to cover the RDL feature. In one step, a patterned photoresist layer is formed over the passivation layer. The patterned photoresist layer has an opening that is disposed over a portion of the RDL feature and that exposes a portion of the passivation layer. In one step, a first etching is performed on the passivation layer with the patterned photoresist layer serving as an etch mask to make the portion of the passivation layer thinner than other portions of the passivation layer that are covered by the patterned photoresist layer. In one step, the patterned photoresist layer is removed after the first etching. In one step, a second etching is performed on the passivation layer after the patterned photoresist layer is removed, such that the portion of the passivation layer is removed and the other portions of the passivation layer remain, so as to form an opening in the passivation layer, and the RDL feature is exposed through the opening of the passivation layer.

In accordance with some embodiments, the first etching is performed to make the portion of the passivation layer have a thickness ranging from 2500 angstroms to 4500 angstroms.

In accordance with some embodiments, the second etching makes the thicknesses of the other portions of the passivation layer range from 5000 angstroms to 11000 angstroms.

In accordance with some embodiments, the second etching is performed using a carbon-free etchant.

In accordance with some embodiments, the second etching is performed using NF₃.

In accordance with some embodiments, the first etching is performed using NF₃.

In accordance with some embodiments, a chip package structure includes a die, a redistribution layer (RDL) feature, and a bare passivation layer. The die is provided with a contact. The RDL feature is formed over the die, and is electrically connected to the contact. The bare passivation layer is disposed over the RDL feature, and has an opening over a portion of the RDL feature. The bare passivation layer has a thickness ranging from 5000 angstroms to 11000 angstroms.

In accordance with some embodiments, the RDL feature is made of copper, the chip package structure further comprising a copper pillar that is disposed over and in contact with the RDL feature through the opening of the bare passivation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a redistribution layer (RDL) structure, comprising steps of:
providing a die with a contact;
forming an RDL feature over the die, the RDL feature being electrically connected to the contact;
forming a passivation layer over the RDL feature;
forming a patterned etch mask layer over the passivation layer, the patterned etch mask layer having an opening over a portion of the RDL feature;
patterning the passivation layer using the patterned etch mask layer disposed on the passivation layer;
removing the patterned etch mask layer after the passivation layer is patterned using the patterned etch mask layer disposed on the passivation layer; and
etching the passivation layer to form a passivation opening in the passivation layer, wherein the portion of the RDL feature is exposed through the passivation opening.

2. The method according to claim 1, wherein the patterned etch mask layer is a photoresist layer, and the step of etching the passivation layer to form the passivation opening is performed after the step of removing the patterned etch mask layer.

3. The method according to claim 2, wherein, in the step of forming the patterned etch mask layer, the opening of the patterned etch mask layer is formed to expose a portion of the passivation layer;
wherein the step of patterning the passivation layer includes:
etching the passivation layer using the patterned etch mask layer disposed on the passivation layer to make the portion of the passivation layer cover the RDL feature with a reduced thickness.

4. The method according to claim 3, wherein the reduced thickness of the portion of the passivation layer ranges from 2500 angstroms to 4500 angstroms.

5. The method according to claim 3, wherein, after the passivation opening is formed, the passivation layer has a thickness ranging from 5000 angstroms to 11000 angstroms.

6. The method according to claim 3, wherein, after the patterned etch mask layer is removed, the portion of the passivation layer is thinner than other portions of the passivation layer; and
wherein, in the step of etching the passivation layer to form the passivation opening, the passivation layer is completely exposed to an etchant that is used to etch the passivation layer.

7. The method according to claim 6, wherein the etchant used in the step of etching the passivation layer to form the passivation opening is a carbon-free etchant.

8. The method according to claim 6, wherein the etchant used in the step of etching the passivation layer to form the passivation opening is NF₃.

9. The method according to claim 8, wherein the etchant used for etching the passivation layer using the patterned etch mask layer disposed on the passivation layer is NF₃.

10. The method according to claim 3, wherein the RDL feature is made of Cu.

11. The method according to claim 1, wherein the patterned etch mask layer is a photoresist layer, and the step of etching the passivation layer to form the passivation opening is performed between the step of patterning the passivation layer and the step of removing the patterned etch mask layer.

12. The method according to claim 11, wherein the etchant used in the step of etching the passivation layer to form the passivation opening is NF₃.

13. A method for forming a redistribution layer (RDL) structure, comprising steps of:
providing a die with a contact;
forming an RDL feature over the die, the RDL feature being electrically connected to the contact;
forming a passivation layer that covers the RDL feature;
forming a patterned photoresist layer over the passivation layer, the patterned photoresist layer having an opening that is disposed over a portion of the RDL feature and that exposes a portion of the passivation layer;
performing a first etching on the passivation layer with the patterned photoresist layer serving as an etch mask to make the portion of the passivation layer thinner than other portions of the passivation layer that are covered by the patterned photoresist layer;
removing the patterned photoresist layer after the first etching; and
performing a second etching on the passivation layer after the patterned photoresist layer is removed, such that the portion of the passivation layer is removed and the other portions of the passivation layer remain, so as to form an opening in the passivation layer, and the RDL feature is exposed through the opening of the passivation layer.

14. The method according to claim 13, wherein the first etching is performed to make the portion of the passivation layer have a thickness ranging from 2500 angstroms to 4500 angstroms.

15. The method according to claim 14, wherein the second etching makes the thicknesses of the other portions of the passivation layer range from 5000 angstroms to 11000 angstroms.

16. The method according to claim 13, wherein the second etching is performed using a carbon-free etchant.

17. The method according to claim 13, wherein the second etching is performed using NF₃.

18. The method according to claim 17, wherein the first etching is performed using NF₃.

19. A chip package structure, comprising:
a die provided with a contact;
a redistribution layer (RDL) feature formed over the die, and electrically connected to the contact; and
a bare passivation layer over the RDL feature, and having an opening over a portion of the RDL feature;
wherein the bare passivation layer has a thickness ranging from 5000 angstroms to 11000 angstroms.

20. The chip package structure according to claim 19, wherein the RDL feature is made of copper, the chip package structure further comprising a copper pillar that is disposed over and in contact with the RDL feature through the opening of the bare passivation layer.
